(19) United States
(12) Patent Application Publication
(10) Pub. No.: US 2025/0283925 A1
(43) Pub. Date: Sep. 11, 2025

(54) METHOD FOR MEASURING AN EARTH RESISTANCE IN A BATTERY CHARGING SYSTEM

(71) Applicants: ELDOR CORPORATION S.P.A., Orsenigo (Como) (IT); DR. ING. H.C. F. PORSCHE AG, Stuttgart (DE)

(72) Inventors: Paolo LISANTI, Orsenigo (Como) (IT); Stefano DATTILO, Orsenigo (Como) (IT); Francesco BERTINO, Orsenigo (Como) (IT); Pasquale FORTE, Orsenigo (Como) (IT)

(21) Appl. No.: 18/861,154

(22) PCT Filed: Apr. 27, 2023
(86) PCT No.: PCT/IB2023/054362

§ 371 Date: Oct. 28, 2024

(30) Foreign Application Priority Data
Apr. 29, 2022 (IT) 102022000008630

(51) Int. Cl. G01R 27/18; B60L 53/62; G01R 23/16; H02J 7/00

(52) U.S. Cl. CPC G01R 27/18; B60L 53/62; G01R 23/16; H02J 7/0029; H02J 2310/48

(57) ABSTRACT

A method for measuring an earth resistance in a battery charging system connected to or connectable to a power grid; includes injecting a first alternating current signal between a first, neutral, node and a second, earth, node, detecting a first voltage signal representing an electrical potential difference between said first and second nodes, calculating an earth resistance value as a function of said first voltage signal, determining a new injection frequency for a subsequent measurement cycle. The determining of a new injection frequency includes detecting a value of the phase shift angle between the first current signal and the first voltage signal in the current measurement cycle, comparing the value of the phase shift angle with at least a first, upper threshold value and/or at least a second, lower threshold value and determining said new injection frequency at least partly as a function of the comparisons.

This invention relates to a method for measuring a ground resistance in a battery charging system, preferably traction (automotive) batteries.

The main application of this invention is in the automotive field, in particular in the design and manufacture of charging systems for electric batteries.

In the context of electric vehicles, in fact, the battery pack charging mode is divided into two distinct relative macro-categories: on-vehicle chargers and ground chargers.

On-board chargers are, as their name suggests, integrated into the vehicle and include all the power and control electronics needed to convert the alternating current from the mains into the direct current needed to charge the battery pack.

On the other hand, ‘ground’ chargers are the usual ‘columns’ or wallboxes that directly perform the conversion by supplying the vehicle with direct current.

It is therefore evident that battery chargers of both categories, having to manage an alternating current coming from the mains and having to convert it into direct current for charging high-voltage batteries, present considerable criticalities from the point of view of user safety, as they must be equipped with appropriate protection systems.

One of the main areas of research relating to safety systems is that of verifying that the vehicle or charging column is correctly ‘earthed’, an operation that in some cases is carried out by injecting a current signal into the network, measuring the resulting voltage by means of appropriate computational calculations, and calculating the relevant earth resistance.

However, this procedure is not without its drawbacks, as its effectiveness is closely linked to the boundary conditions, i.e. the noise of the network.

Considering that the distribution network sees a large number of users with the most varied applications connected to the same substation, it is not rare that the frequency used in the generation of the current signal is already occupied by very significant disturbances.

This, considering the stringent regulatory constraints that limit the current intensity that can be used for measurement to little more than 1 mA, entails in several cases a real difficulty in determining which component of the voltage signal detected is to be correlated with the injected signal and which is instead the noise component.

It must also be considered that the amount and type of loads that are connected to the network is not to be considered a constant parameter, but varies over time, even significantly, which led the Applicant to study a possible solution that would make the system robust to these variables.

It is therefore the purpose of this invention to provide a method for measuring an earth resistance in a battery charging system that is able to overcome the above-mentioned drawbacks of the known technique.

In particular, the object of the present invention is to provide a method for measuring an earth resistance in a battery charging system that maintains its efficiency regardless of the type and number of loads connected to the network.

Said purposes are achieved with a method for measuring a ground resistance in a battery charging system having the characteristics of one or more of the following claims.

More particularly, the method comprises, for each measurement cycle, injecting a first alternating current signal between a first neutral node and a second earth node.

This signal has a predetermined duration and a predetermined injection frequency.

The injection frequency is preferably contained in either a first, low-frequency range or a second, high-frequency range.

The method further comprises detecting a first voltage signal representing an electrical potential difference between said first and second nodes, calculating an earth resistance value as a function of said first voltage signal and determining a new injection frequency for a subsequent measurement cycle.

These steps are repeated recursively, at predetermined sampling ranges.

According to one aspect of the invention, the step of determining a new injection frequency for a subsequent measurement cycle comprises the steps of detecting a value of a phase-shift angle between said first current signal and said first voltage signal in the current measurement cycle and comparing said phase-shift angle value with at least a first, upper, threshold value and/or at least a second, lower, threshold value.

Preferably, the new injection frequency is determined at least in part as a function of said comparisons.

Advantageously, the use of the phase-shift angle as a parameter indicating the contribution of the capacitive loads makes it possible to identify conditions in which the selected frequency range could lead to inaccurate measurements, allowing it to be modified in good time.

Preferably, this step of determining the new injection frequency is carried out according to the following logic:
identifying a new injection frequency contained in the first range, if said offset angle is greater than the first threshold value and the injection frequency of the current measurement cycle is contained in the second range;
identifying a new injection frequency contained in the second range, if said phase shift angle is less than the second threshold value and the injection frequency of the current measurement cycle is contained in the first range
identifying a new injection frequency corresponding to the injection frequency of the current measurement cycle or contained within the same range as the injection frequency of the current measurement cycle if neither of the two previous conditions occurs.

Advantageously, the method thus allows the signal to be injected at each measurement cycle at an optimal frequency value.

In this respect, in fact, it is important to highlight that the ground mesh is composed both of the earth resistance and, in parallel, of an equivalent capacity as a function of the loads attached to the same grid, which may, thus, change over time.

The phase shift angle makes it possible to measure the division between the resistance and capacity of the earth impedance:
the more the phase shift angle reduces the more the impedance is “resistive”, since in purely resistive circuits this phase shift is, ideally, zero;
in contrast, as this phase shift angle increases (up to) 90° the impedance becomes “capacitive”, since in purely capacitive circuits this phase shift ideally sees the current in advance by 90°.

The effect of the capacity depends, therefore, on the injection frequency; this is why, by injecting a direct current DC, it would be possible to cancel the effect of the capacity.

This solution, in any case, is not practicable, since any disturbance in direct current present on the ground mesh (e.g. another similar/redundant measurement device) would lead to errors or uncertainties in the measurement.

In addition, on a line protected by a Type A RCD, for safety reasons, a direct current greater than 6 mA cannot circulate, hugely reducing the number of DC devices that may inject a DC current on the same line.

As a consequence, the only possibility for performing the measurement is the injection of an alternating current, which, as mentioned, is variable over time, due to the capacitive contribution.

Using the method that is the subject of the invention, this, in any case, does not entail any problem, since the monitoring of the phase shift angle makes it possible to adapt the injected signal to the surrounding conditions in real time:
if the value of the phase shift angle is high, and thus the capacitive contribution is high, a low-frequency current is injected (in the LF range), which, in any case, brings the signal closer to the fundamental frequency of the 50/60 Hz grid, the source of disturbances;
for this reason, as soon as the capacitive contribution decreases, i.e. the phase shift angle is reduced below a threshold, one shifts into the high-frequency range to be removed from said fundamental frequency.

The dependent claims, incorporated herein by reference, correspond to different embodiments of the invention.

Further features and advantages of this invention will become clearer from the indicative, and therefore non-limiting, description of a preferred, but not exclusive embodiment of a method for measuring an earth resistance in a battery charging system, as illustrated in the accompanying drawings wherein

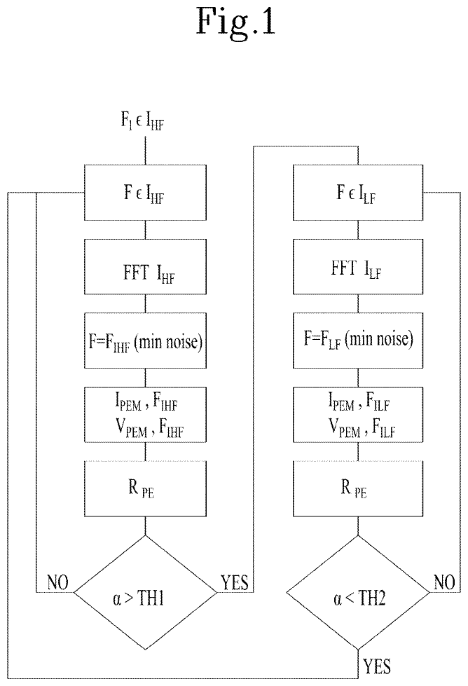

FIG. 1 shows a block diagram of the method that this invention concerns.

With reference to the appended FIGURES, a method for measuring an earth resistance in a battery charging system according to this invention is generically identified by numerical reference 1.

Purely by way of example, a method 1 carried out within an on-board charger 100 will be described herein, without, however, this description being intended to define a limitation to the application and scope of the invention.

A similar description could be provided for earth charging systems, such as, for example, columns or wall-boxes, but since the measurement of the earth resistance is a more critical parameter within vehicles, it was preferred, in the following, to provide a description of the application in which the invention finds greater benefit.

It should be noted that the expression on-board charger is intended in this text to define in a generic way any charging system for a traction battery pack capable of connecting to the alternating current electrical network and converting it to direct current before supplying power to the battery.

For this reason, the battery charger comprises at least one casing (earthed) associated with a mains connection socket and containing a converter unit configured to convert the alternating current from the mains into a direct current useful for charging the battery pack.

The connection socket is thus configured to receive the phases and/or the neutral.

The method 1 for measuring the earth resistance that is the subject of the invention involves injecting (i.e. generating) an alternating current signal between a first neutral node and a second earth node.

The measurement signal is preferably generated by means of a current generator.

Note that the neutral node may alternatively be
a physical node in the network (i.e. a node directly connected to the neutral of the connection socket);
a reconstructed virtual node with potential corresponding to the earth potential.

Preferably, a network noise analysis is also performed prior to the generation or injection of the phase measurement signal.

This network noise analysis step involves detecting a reference signal representing the network voltage and identifying a free frequency range in which said voltage signal has a minimum or zero value (e.g. minimum or zero amplitude).

More precisely, a spectral analysis of said reference signal is performed and a predetermined injection frequency F1 of the first current signal is identified as the frequency with the lowest spectral content.

In the preferred embodiment, the spectral analysis is not performed on the entire frequency spectrum, but only on, alternatively, a first, low-frequency I_LF range or a second, high-frequency I_HF range.

Advantageously, this speeds up and optimises the analysis.

Preferably, at the start of the method, i.e. at the connection of the charger with the mains, the set frequency is selected within the second, high-frequency I_HF range.

Note that, preferably, the first, low-frequency range is between 0 Hz and 200 Hz, more preferably between 5 Hz and 150 Hz.

The second, high frequency, range is preferably between 200 Hz and 600 Hz, more preferably between 250 Hz and 400 Hz.

The method thus involves detecting a first voltage signal representing an electrical potential difference between said first and second node and calculating an earth resistance value as a function of said first voltage signal.

Said steps are known, already patented by the Applicant under Italian patent application 102020000031625, incorporated herein by reference.

For this reason, the steps for measuring the earth resistance will not be further detailed.

According to the invention, at the end of each measurement cycle (or during said cycle), a new injection frequency F is determined for a subsequent measurement cycle.

Preferably, the step of determining a new injection frequency F for the subsequent measurement cycle comprises detecting a value of the phase shift angle α between said first current signal and said first voltage signal in the current measurement cycle.

The phase shift angle value a is then compared with at least one first, upper, threshold value TH_1 and/or at least one second, lower, threshold value TH_2.

Preferably, said first, upper, threshold value is between 50° and 75°. Preferably, said second, lower, threshold value is between 0° and 15°.

The new injection frequency F is thus determined, at least in part, as a function of and in accordance with said comparisons.

Preferably, the determination of the new injection frequency is carried out according to the following logic:
identifying a new injection frequency F contained in the first range I_LF, if said phase shift angle α is greater than the first threshold value TH_1 and the injection frequency of the current measurement cycle is contained in the second range I_HF;
identifying a new injection frequency F contained in the second I_HF range, if said phase shift angle α is less than the second threshold value TH_2 and the injection frequency F of the current measurement cycle is contained in the first I_LF range;
identifying a new injection frequency F corresponding to the injection frequency F of the current measurement cycle or contained within the same range as the injection frequency F of the current measurement cycle if neither of the preceding two conditions occurs.

Preferably, moreover (and by analogy with the determination of the predetermined frequency), said steps of identifying a new injection frequency F involve performing a network noise analysis step within the selected frequency range; said noise analysis step involves:
detecting a reference signal representing the mains voltage;
performing a spectral analysis of said reference signal;
identifying the new injection frequency F as the frequency with the lowest spectral content.

Advantageously, moreover, said method may be used within methods and protection devices for the battery charger, which are also (independently) the subject of this invention.

Along the lines of the measurement method described herein, in fact, it is possible to compare the earth resistance value with a reference limit value (preferably less than 300 ohms), isolating the converter unit of the charger device from the mains if said earth resistance value exceeds said reference limit value.

The invention achieves the intended purposes and important advantages result.

In fact, the use of a recursive method that monitors the phase-shift angle between the current and the voltage of the injected signal allows a rapid and accurate monitoring of the contribution of inductive loads and of a possible overcrowding of the selected frequency range, allowing a rapid shift of the reference band with consequent optimisation of the detection.

1. A method for measuring an earth resistance in a battery charging system connected to or connectable to a power grid; said method comprising, for each measurement cycle, the steps of:
a) injecting a first alternating current signal between a first, neutral, node and a second, earth, node; said first current signal having a pre-set duration and a pre-set injection frequency either contained within a first, low frequency, range, or within a second, high frequency, range;
b) detecting a first voltage signal representing an electrical potential difference between said first and said second nodes;
c) calculating an earth resistance value as a function of said first voltage signal;
d) determining a new injection frequency for a subsequent measurement cycle;
e) recursively repeating steps a) to d);
wherein said step of determining a new injection frequency for a subsequent measurement cycle comprises the steps of:
detecting a value of the phase shift angle between said first current signal and said first voltage signal in the current measurement cycle;
comparing said value of the phase shift angle with at least a first, upper threshold value and/or at least a second, lower threshold value;
determining said new injection frequency at least partly as a function of said comparisons.

2. The method according to claim 1, wherein said step of determining the new injection frequency is carried out according to the following logic:
identifying a new injection frequency contained within the first range, if said phase shift angle is higher than the first threshold value and the injection frequency of the current measurement cycle is contained within the second range;
identifying a new injection frequency contained within the second range, if said phase shift angle is less than the second threshold value and the injection frequency of the current measurement cycle is contained within the first range;
identifying a new injection frequency corresponding to the injection frequency of the current measurement cycle or contained within the same range as the injection frequency of the current measurement cycle if neither of the above conditions is true.

3. The method according to claim 1, wherein said steps of identifying a new injection frequency comprise a step of analysing the grid noise within the selected frequency range; said noise analysis step comprises:
detecting a reference signal representing the grid voltage;
performing a spectral analysis of said reference signal;
identifying the new injection frequency as the frequency with the lowest spectral content.

4. The method according to claim 1, wherein said pre-set injection frequency is selected within the second, high frequency range.

5. The method according to claim 1, wherein said first, low frequency range is between 0 Hz and 200 Hz, preferably between 5 Hz and 150 Hz.

6. The method according to claim 1, wherein said second, high frequency range is between 200 Hz and 600 Hz, preferably between 250 Hz and 400 Hz.

7. The method according to claim 1, wherein said first, upper threshold value is between 50° and 75°.

8. The method according to claim 1, wherein said second, lower threshold value is between 0° and 15°.

9. The method according to claim 1, wherein said second, neutral node can be, alternatively:
a physical grid node;
a reconstructed virtual node with a potential corresponding to the earth potential and in electrical continuity with the phases.

10. A method for protecting a battery charging system, comprising the steps of:
measuring an earth resistance in a battery charging device by implementing the measurement method according to claim 1;
comparing said earth resistance value with a reference limit value of the earth resistance;
insulating a converter assembly of the battery charging device from the power grid when said earth resistance value exceeds said reference limit value of the earth resistance.
